(19) United States
(12) Patent Application Publication
(10) Pub. No.: US 2025/0015166 A1
(43) Pub. Date: Jan. 9, 2025

(54) SEMICONDUCTOR DEVICES AND METHODS FOR MANUFACTURING

(71) Applicant: Taiwan Semiconductor Manufacturing Company, Ltd., Hsinchu (TW)

(72) Inventors: Tzu-Ging Lin, Kaohsiung (TW); Yi-Chun Chen, Hsinchu (TW); Jih-Jse Lin, Taipei (TW)

(73) Assignee: Taiwan Semiconductor Manufacturing Company, Ltd., Hsinchu (TW)

(21) Appl. No.: 18/348,064

(22) Filed: Jul. 6, 2023

(51) Int. Cl. H01L 29/66; H01L 21/3065; H01L 29/78

(52) U.S. Cl. CPC H01L 29/66795; H01L 21/3065; H01L 29/66545; H01L 29/7851

(57) ABSTRACT

Semiconductor devices and methods of fabrication are provided. A method includes providing a semiconductor structure with a first sidewall distanced from a second sidewall, fins located between the first sidewall and the second sidewall, and isolation regions located between the first sidewall and the second sidewall, wherein adjacent fins are separated by a respective isolation region. The method further includes performing a plasma etching process to etch the fins and the isolation regions, wherein the plasma etching process chemically etches the fins, wherein the plasma etching process physically etches the isolation regions to recesses defining a crown-shaped depth profile.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a plan view of a layout of a multi-gate device, in accordance with some embodiments.

FIGS. 2-13 are views of a multi-gate device during successive stages of fabrication, in accordance with some embodiments, wherein FIGS. 2, 5, 8, and 11 are perspective views at successive stages, wherein FIGS. 3, 6, 9, and 12 are X-cut cross-sectional views of the multi-gate device of the preceding perspective view, and FIGS. 4, 7, 10, and 13 are Y-cut cross-sectional views of the multi-gate device of the preceding perspective view, in accordance with some embodiments.

FIG. 14 is a Y-cut cross-sectional view of a multi-gate device, similar to FIG. 13, but having a larger trench and greater number of fins and isolation regions, in accordance with some embodiments.

FIG. 15 is a Y-cut cross-sectional view of the multi-gate device of FIG. 14, after performing an etching process, in accordance with some embodiments.

FIG. 16 is a Y-cut cross-sectional view of the multi-gate device of FIG. 15, after performing a deposition process, in accordance with some embodiments.

FIG. 17 is a TEM view along a Y-cut of a multi-gate device, illustrating the etching depth of the etching process, in accordance with some embodiments.

FIG. 18 is a TEM view along an X-cut cross-sectional view of the multi-gate device of FIG. 15, in accordance with some embodiments.

FIG. 19 is a flow chart illustrating a method, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. Methods described herein may be easily integrated into the current process flow. Further, methods described herein relate to the formation of an insulation structure, such as a Continuous Poly On Diffusion Edge (CPODE) structure, that insulates adjacent devices from one another. In certain embodiments, a portion of a selected fin or fins is removed and replaced with insulation material.

In certain embodiments, a continuous poly on diffusion edge (CPODE) process is used to provide isolation structures between adjacent devices. For purposes of this disclosure, a “diffusion edge” may be equivalently referred to as an active edge, where for example an active edge abuts adjacent active regions. Further, an active region includes a region where transistor structures are formed (e.g., including source, drain, and gate/channel structures). In some examples, active regions may be disposed between insulating regions. The CPODE process may provide an isolation structure between neighboring active regions, and thus neighboring transistors, by performing a plasma etching process along an active edge (e.g., at a boundary of adjacent active regions) to form a cut region, and by filling the cut region with a dielectric, such as silicon nitride (SiN).

In embodiments herein, a CPODE-last processing method, i.e., after metal gate formation, enables high overlay tolerance by self-aligning structures. Further, CPODE-last processing methods provide for lower epitaxial layer stress, particularly when compared to CPODE-first processing which suffers epitaxial stress release during the etch process.

Embodiments of the present disclosure offer advantages over the existing art, though it is understood that other embodiments may offer different advantages, not all advantages are necessarily discussed herein, and no particular advantage is required for all embodiments.

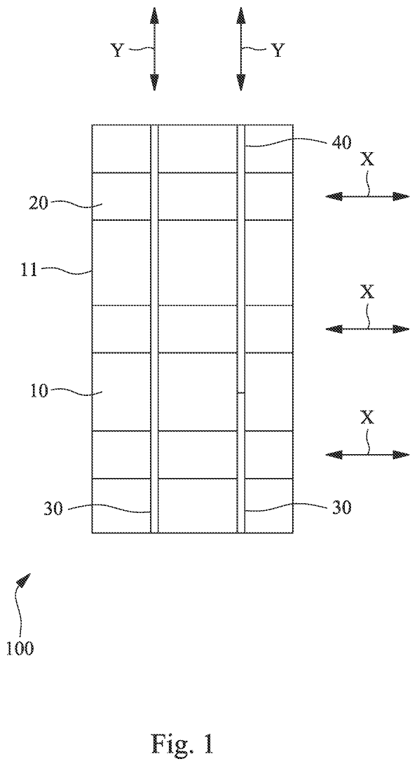

For purposes of the discussion that follows, FIG. 1 provides a simplified top-down layout view of a semiconductor device 100, such as a multi-gate device 100. In various embodiments, the multi-gate device 100 may include a FinFET device, a GAA transistor, or other type of multi-gate device. The multi-gate device 100 is formed over a substrate 10. In some embodiments, the substrate 10 may be a semiconductor substrate such as a silicon substrate.

FIG. 1 illustrates a unit cell 11, i.e., a portion of the semiconductor substrate 10. As shown, parallel active regions 20 are spaced apart from one another and extend in an X-direction. Further, parallel gate lines 30 are spaced apart from one another and extend in a Y-direction perpendicular to the X-direction. In some embodiments, gate lines 30 are formed from conductive material such as metal and form gate structures for the multi-gate device 100.

As further shown in FIG. 1, a cut region or trench is formed in one gate line 30 and is filled with isolation 40. Such isolation 40 may isolate adjacent devices from one another as described below.

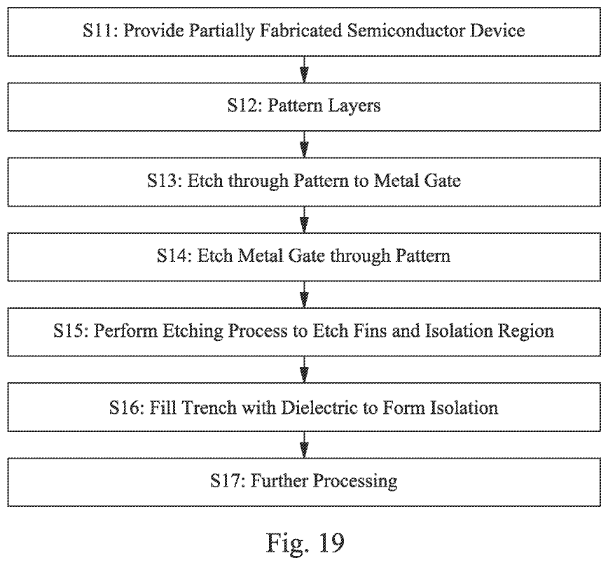

Referring to FIG. 19, illustrated therein is a method 1000 of fabrication of a semiconductor device 100 (such as a multi-gate device) using a CPODE process, in accordance with various embodiments. Method 1000 is discussed below with reference to a FinFET device. However, it will be understood that aspects of method 1000, including the disclosed CPODE process, may be equally applied to other types of multi-gate devices without departing from the scope of the present disclosure. In some embodiments, method 1000 may be used to fabricate the multi-gate device 100, described above with reference to FIG. 1. Thus, one or more aspects discussed above with reference to the multi-gate device 100 may also apply to method 1000. It is understood that method 1000 includes steps having features of a complementary metal-oxide-semiconductor (CMOS) technology process flow and thus, are only described briefly herein. Also, additional steps may be performed before, after, and/or during method 1000.

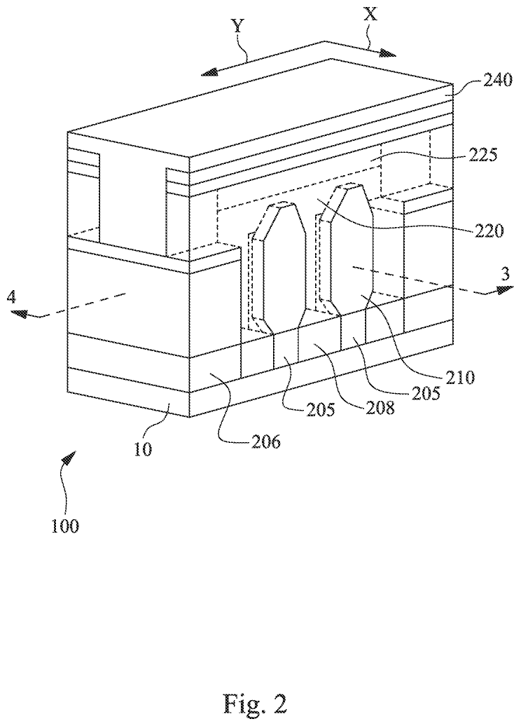

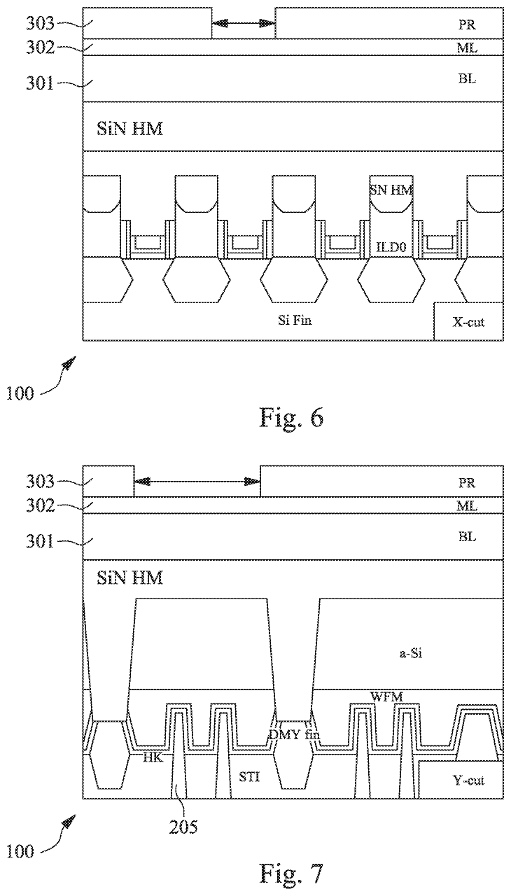

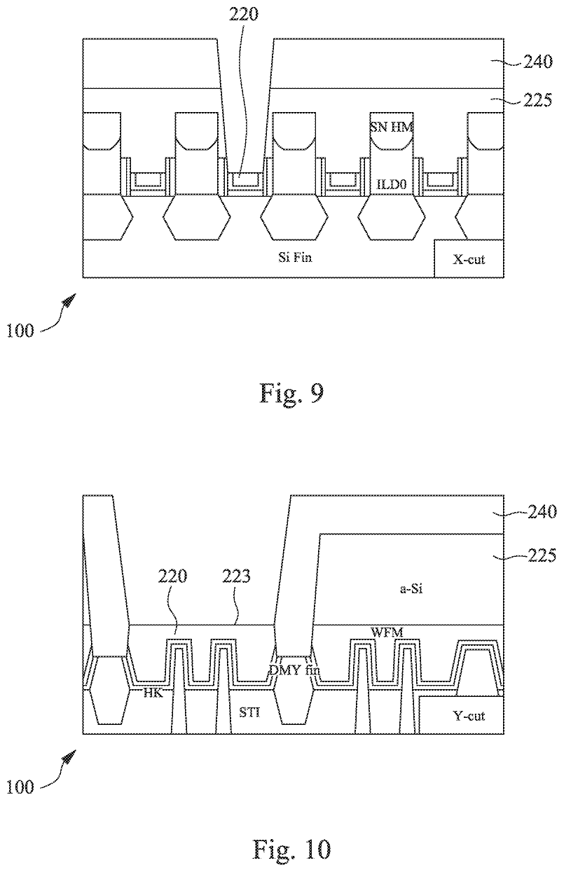

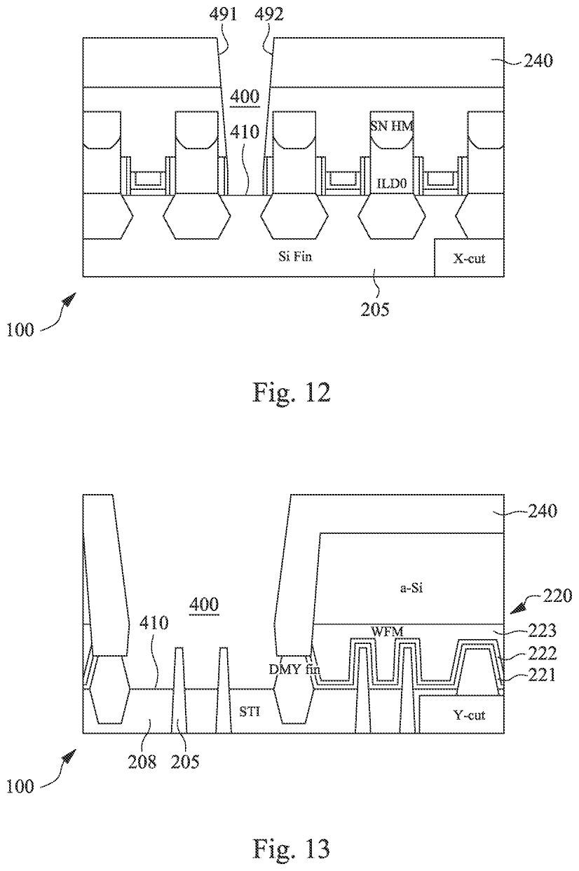

The method 1000 of FIG. 19 is described below with reference to FIGS. 2-15 which illustrate the semiconductor device 100 at various stages of fabrication according to method 1000.

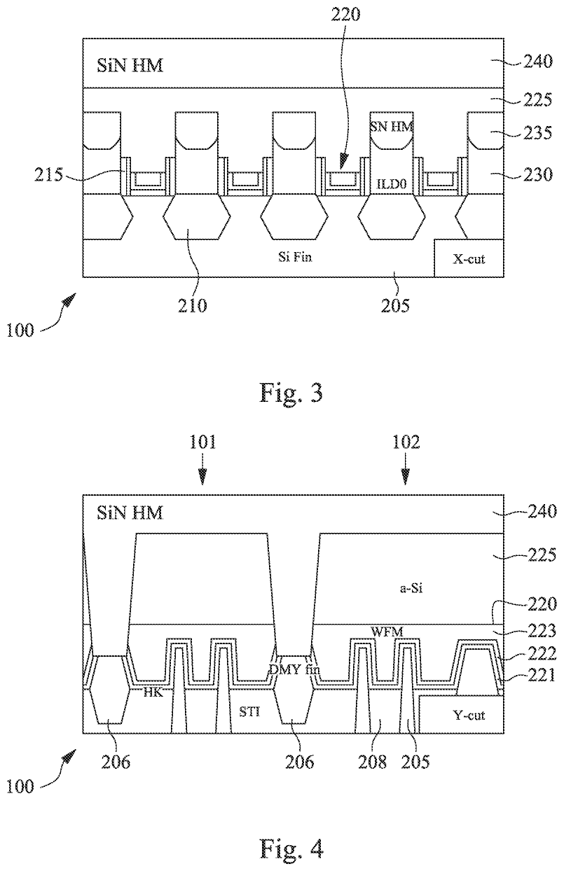

FIG. 2 illustrates a perspective view of a portion of an intermediate structure in forming a device 100, such as a FinFET semiconductor device, according to some embodiments. FIG. 3 is a cross-sectional view taken along line 3 in FIG. 2, i.e., an X-cut in which the vertical direction is defined by the Z-axis and the lateral direction is defined by the X-axis. FIG. 4 is a cross-sectional view taken along line 4 in FIG. 2, i.e., a Y-cut in which the vertical direction is defined by the Z-axis and the lateral direction is defined by the Y-axis. It is understood that method 1000 includes steps having features of a complementary metal-oxide-semiconductor (CMOS) technology process flow and thus, are only described briefly herein. Also, additional steps may be performed before, after, and/or during method 1000.

Referring now to FIGS. 19 and 2-4, a method 1000 for fabricating a semiconductor device 100 includes, at S11, providing a partially-fabricated semiconductor device 100 as shown in FIGS. 2-4. For example, method 1000 includes providing a substrate 10 for processing. In an embodiment the substrate 10 is a semiconductor substrate, which may be, for example, a silicon substrate, a silicon germanium substrate, a germanium substrate, a III-V material substrate (e.g., GaAs, GaP, GaAsP, AlInAs, AlGaAs, GaInAs, InAs, GaInP, InP, InSb, and/or GaInAsP; or a combination thereof), or a substrate formed of other semiconductor materials with, for example, high band-to-band tunneling (BTBT). The substrate 10 may be doped or un-doped. In some embodiments, the substrate 10 may be a bulk semiconductor substrate, such as a bulk silicon substrate that is a wafer, a semiconductor-on-insulator (SOI) substrate, a multi-layered or gradient substrate, or the like.

The method 1000 includes forming fins 205 over the substrate 10, such as from the substrate 10. The fins 205 are patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

In some embodiments, the entire fins 205 are formed of crystalline Si. In other embodiments, at least a channel region of the fins 205 includes SiGe where a content of Ge is in a range from about 20 atomic % to 50 atomic %. When a SiGe channel is employed, a SiGe epitaxial layer is formed over substrate 10 and patterning operations are performed. In some embodiments, one or more buffer semiconductor layers having a lower Ge concentration than the channel region are formed over the substrate 10.

As shown, the fins 205 extend in the X-direction and are spaced apart from one another in the Y-direction. In some embodiments, one or more dummy fins 206 are formed adjacent to the fins 205 of an active FinFET.

After the fins 205 are formed, an insulating layer of isolation regions 208 is disposed over the fins 205 and the substrate 10. In some embodiments, isolation insulating regions 208 is a “shallow-trench-isolation (STI)” layer filled with an insulating material. The insulating material for the isolation insulating regions 208 may include silicon oxide, silicon nitride, silicon oxynitride (SiON), SiOCN, fluorine-doped silicate glass (FSG), or a low-k dielectric material or other suitable material.

In some embodiments, the isolation insulating regions 208 includes one or more layers of insulating materials, for example, silicon dioxide, silicon oxynitride and/or silicon nitride formed by LPCVD (low pressure chemical vapor deposition), plasma-CVD or flowable CVD. In flowable CVD, flowable dielectric materials instead of silicon oxide are deposited. Flowable dielectric materials, as their name suggests, can “flow” during deposition to fill gaps or spaces with a high aspect ratio. Usually, various chemistries are added to silicon-containing precursors to allow the deposited film to flow. In some embodiments, nitrogen hydride bonds are added. Examples of flowable dielectric precursors, particularly flowable silicon oxide precursors, include a silicate, a siloxane, a methyl silsesquioxane (MSQ), a hydrogen silsesquioxane (HSQ), an MSQ/HSQ, a perhydrosilazane (TCPS), a perhydro-polysilazane (PSZ), a tetraethyl orthosilicate (TEOS), or a silyl-amine, such as trisilylamine (TSA). These flowable silicon oxide materials are formed in a multiple-operation process. After the flowable film is deposited, it is cured and then annealed to remove un-desired element(s) to form silicon oxide. When the un-desired element(s) is removed, the flowable film densifies and shrinks. In some embodiments, multiple anneal processes are conducted. The flowable film is cured and annealed more than once. The flowable film may be doped with boron and/or phosphorous. The isolation insulating regions 208 is formed by one or more layers of SOG, SiO, SiON, SiOCN or fluorine-doped silicate glass (FSG) in some embodiments.

After forming the isolation insulating regions 208 over the fins 205, a planarization operation is performed so as to remove part of the isolation insulating regions 208. The planarization operation may include a chemical mechanical polishing (CMP) and/or an etch-back process. Subsequently, portions of the isolation insulating regions 208 extending over the top surfaces of the fins 205 are removed using, for example, an etch process, chemical mechanical polishing (CMP), or the like. Further, the isolation insulating regions 208 is recessed to expose the upper portion of the fins 205. In some embodiments, the isolation insulating regions 208 is recessed using a single etch process, or multiple etch processes. In some embodiments in which the isolation insulating regions 208 is made of silicon oxide, the etch process is a dry etch, a chemical etch, or a wet cleaning process. In certain embodiments, the partially removing the isolation insulating regions 208 is performed using a wet etching process, for example, by dipping the substrate in hydrofluoric acid (HF). In another embodiment, the partially removing the isolation insulating regions 208 is performed using a dry etching process. For example, a dry etching process using CHF3 or BF3 as etching gases may be used.

After forming the isolation insulating regions 208, a thermal process, for example, an anneal process, may be performed to improve the quality of the isolation insulating regions 208. In certain embodiments, the thermal process is performed by rapid thermal annealing (RTA) at a temperature in a range of about 900° C. to about 1050° C. for about 1.5 seconds to about 10 seconds in an inert gas ambient, such as an N2, Ar or He ambient.

As shown in FIGS. 2-4, the fins 205 extend in the X direction and are arranged and spaced apart in the Y direction with an equal pitch in some embodiments.

After the fins 205 and the isolation insulating regions 208 are formed, a sacrificial gate structure (not shown) including a sacrificial gate dielectric layer and a sacrificial gate electrode layer are formed over the exposed fins 205, which are subsequently used as channel layers of a gate region. The sacrificial gate dielectric layer and the sacrificial gate electrode layer are subsequently used to define and form source/drain regions. In some embodiments, the sacrificial gate dielectric layer and the sacrificial gate electrode layer are formed by first depositing and patterning a sacrificial gate dielectric layer formed over the exposed fins 205 and then a dummy electrode layer over the sacrificial gate dielectric layer. The sacrificial gate dielectric layer may be formed by thermal oxidation, CVD, sputtering, or any other methods known and used in the art for forming a sacrificial gate dielectric layer. In some embodiments, the sacrificial gate dielectric layer is made of one or more suitable dielectric materials such as silicon oxide, silicon nitride, SiCN, SiON, and SiN; low-k dielectrics, such as carbon doped oxides; extremely low-k dielectrics, such as porous carbon doped silicon dioxide; a polymer, such as polyimide; the like, or a combination thereof. In some embodiments, SiO2 is used.

Subsequently, the sacrificial gate electrode layer is formed over the sacrificial gate dielectric layer. In some embodiments, the sacrificial gate electrode layer is a conductive material and is selected from a group including amorphous silicon, poly silicon, amorphous germanium, poly germanium, amorphous silicon-germanium, poly silicon-germanium, metallic nitrides, metallic silicides, metallic oxides, and metals. The sacrificial gate electrode layer may be deposited by PVD, CVD, sputter deposition, or other techniques known and used in the art for depositing conductive materials. Other materials, conductive and non-conductive, may be used. In one embodiment, polysilicon is used.

A mask pattern may be formed over the sacrificial gate electrode layer to aid in the patterning. The mask pattern includes a first mask layer and a second mask layer disposed on the first mask layer. The mask pattern includes one or more layers of SiO2, SiCN, SiON, aluminum oxide, silicon nitride, or other suitable materials. In some embodiments, the first mask layer includes silicon nitride or SiON and the second mask layer includes silicon oxide. By using the mask pattern as an etching mask, the dummy electrode layer is patterned into the sacrificial gate electrode layer. In some embodiments, the dielectric layer is also patterned to define the sacrificial gate dielectric layer. The fins 205 extend in the X direction and the sacrificial gate structure extends in the Y direction substantially perpendicular to the X direction.

Further, sidewall spacers 215 are formed on opposing sidewalls of the sacrificial gate structure. The sidewall spacers 215 include one or more dielectric layers. In one embodiment, the sidewall spacers 215 are made of one or more of silicon oxide, silicon nitride, SiOCN, SiCN, aluminum oxide, AlCO or AlCN, or any other suitable dielectric material. A blanket layer of a side-wall insulating material may be formed by CVD, PVD, ALD, or other suitable technique. Then, anisotropic etching is performed on the side-wall insulating material to form a pair of side-wall insulating layers (sidewall spacers 215) on two main sides of the sacrificial gate structure.

Subsequently, areas of the fins 205 for forming source/drain regions are recessed down below the upper surface of the isolation insulating regions 208 in some embodiments. Then, source/drain regions 210 are formed over the recesses in the fins 205. As used herein, “source/drain region(s)” may refer to a source region or a drain region, individually or collectively depending on the context. In some embodiments, each source/drain epitaxial region 210 is a merged epitaxial layer. In other embodiments, each source/drain epitaxial region 210 is individually formed over the recesses in the fins 205 without merging with the adjacent source/drain epitaxial region 210.

The materials used for the source/drain epitaxial regions 210 may be varied for the n-type and p-type FinFETs, such that one type of material is used for the n-type FinFETs to exert a tensile stress in the channel region and another type of material is used for the p-type FinFETs to exert a compressive stress. For example, SiP or SiC may be used to form n-type FinFETs, and SiGe or Ge may be used to form p-type FinFETs. In some embodiments, boron (B) is doped in the source/drain epitaxial layer for the p-type FinFETs. Other materials can be used. In some embodiments, the source/drain epitaxial regions 210 include two or more epitaxial layers with different compositions and/or different dopant concentrations. The source/drain epitaxial regions 210 can be formed by CVD, ALD, molecular beam epitaxy (MBE), or any other suitable methods.

After the source/drain epitaxial regions 210 are formed, an interlayer dielectric (ILD) layer 230 is formed. In some embodiments, before forming the ILD layer 230, an etch stop layer (ESL) is formed over the source/drain epitaxial regions 210 and sidewall spacers 215. The ESL is made of silicon nitride or a silicon nitride-based material (e.g., SiON, SiCN or SiOCN) in some embodiments. The materials for the ILD layer 230 include compounds comprising Si, O, C and/or H, such as silicon oxide, SiCOH and SiOC. Organic materials, such as polymers, are used for the ILD layer 230 in some embodiments.

After the ILD layer 230 is formed, a planarization operation, such as an etch-back process and/or a chemical mechanical polishing (CMP) process, is performed to expose the upper surface of the sacrificial gate electrode layer.

Then, the sacrificial gate electrode layer is removed, thereby forming a gate space (not shown). A hard mask 235 may be formed over the interlayer dielectric 230. When the sacrificial gate electrode layer is polysilicon and the ILD layer 230 is silicon oxide, a wet etchant such as a tetramethylammonium hydroxide (TMAH) solution is used to selectively remove the sacrificial gate electrode layer in some embodiments. In some embodiments, the sacrificial gate dielectric layer is subsequently removed using a suitable etching operation. In some embodiments, a portion of the fin 205 below the gate space which is between the source/drain regions of the fins 205 is selected and trimmed.

A metal gate 220 is subsequently formed in the gate space, as shown in FIGS. 2-4. The metal gate 220 may include a gate dielectric layer 221 formed over the channel region of the fin 205. The metal gate 220 may further include a plurality of work function metal layers 222 formed over the gate dielectric layer 221 in the gate space. Further, the metal gate 220 may include a metal gate electrode layer 223 formed over the work function metal layers 222.

In some embodiments, the gate dielectric layer 221 includes one or more layers of a dielectric material, such as silicon oxide, silicon nitride, or a high-k dielectric material, other suitable dielectric material, and/or combinations thereof. Examples of high-k dielectric materials include HfO2, HfSiO, HfSiON, HfTaO, HfTiO, HfZrO, zirconium oxide, aluminum oxide, titanium oxide, hafnium dioxide-alumina (HfO2-Al2O3) alloy, La2O3, HfO2-La2O3, Y₂O₃ or other suitable high-k dielectric materials, and/or combinations thereof. High-k dielectric materials are materials that have a dielectric constant (k) greater than about 3.9 (i.e., greater than silicon dioxide). The gate dielectric layer 221 may be formed by CVD, ALD or any suitable method. In one embodiment, the gate dielectric layer 221 is formed using a highly conformal deposition process such as ALD in order to ensure the formation of a gate dielectric layer having a uniform thickness around each channel layer.

In some embodiments, the work function metal layers 222 are made of a conductive material such as a single layer of TaN, TiN, WN, TiC, WCN, MoN, Co, TaSiN, TiAl, TiAlC, TaAl, TiAlN, and TaAlC or a multilayer of two or more of these materials. The work function metal layers 222 may be formed by ALD, CVD, PVD, or any suitable method. For the n-channel FET, an aluminum containing layer, such as TiAl, TiAlC, TaAl, TiAlN, and/or TaAlC is used as an n-type WFM layer, and for the p-channel FET, one or more of TaN, TiN, WN, TiC, TaSiN, and/or Co is used as a p-type WFM layer, in some embodiments.

In some embodiments, the gate stack structure includes two types of work function metal (WFM) layers 222, a first type WFM used for forming p-type conductivity type structures and a second type WFM used for forming n-type conductivity structures.

The semiconductor device may include p-type structures (i.e., pFET) or n-type structures (i.e., nFET). In some embodiments, a semiconductor device includes both pFET and nFET structures on the same substrate. In some embodiments, a pFET structure includes one or more first type work function metal (p-type WFM) layers disposed over gate dielectric layer and one or more second type work function metal (n-type WFM) layers disposed over the p-type WFM layers. In some embodiments, an nFET structure includes one or more n-type WFM layers disposed over gate dielectric layer and one or more p-type WFM layers disposed over the n-type WFM layers. The number of WFM layers may be selected to tune the threshold voltage Vt. For example, an ultra low voltage threshold (uLVT) device may only have one p-type WFM layer, while a low voltage threshold (LVT) device has two p-type WFM layers, and a standard voltage threshold (SVT) device may have three p-type WFM layers or a thicker p-type WFM layer.

The metal gate electrode layer 223 is formed over the WFM layers 222 and fills the remaining open volume of the gate space. In some embodiments, the metal gate electrode layer 223 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof.

As shown, the method 1000 may further form a gate electrode layer 225 over the metal gate 220. The gate electrode layer 225 may include a semiconductor material such as polysilicon, amorphous silicon, or the like.

As shown, the method 1000 may include etching through the electrode layer 225 and metal gate 220 to electrically separate device region 101 from device region 102. Specifically, such an etch may land on dummy fins 206 located between active FinFET regions 101. As shown, a hardmask 240 is then deposited over the gate electrode 225 and extends to the dummy fins 206. In some embodiments, the hardmask 240 is silicon nitride.

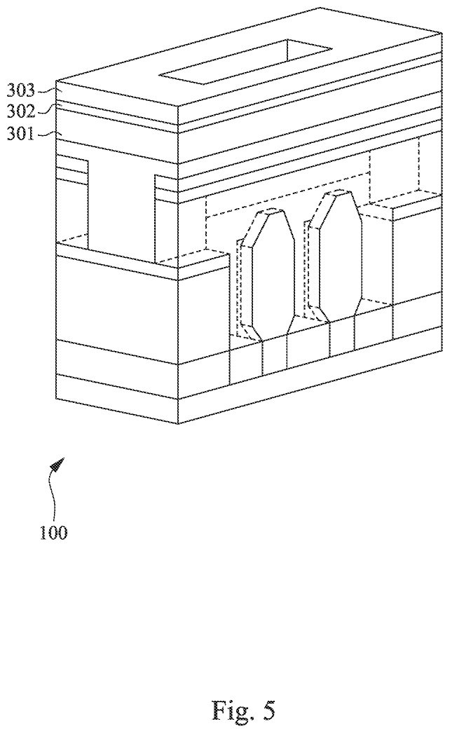

Referring now to FIGS. 19 and 5-7, method 1000 may begin a CPODE process. Specifically, at S12, method 1000 includes forming patterning layers over the partially fabricated device 100. As shown, a bottom layer 301, middle layer 302, and photoresist layer 303 are deposited over the partially fabricated device 100. Then, the photoresist layer 303 is processed, i.e., exposed and/or developed, to form an opening 305 over the material to be removed during the CPODE process, i.e., selected fins 205.

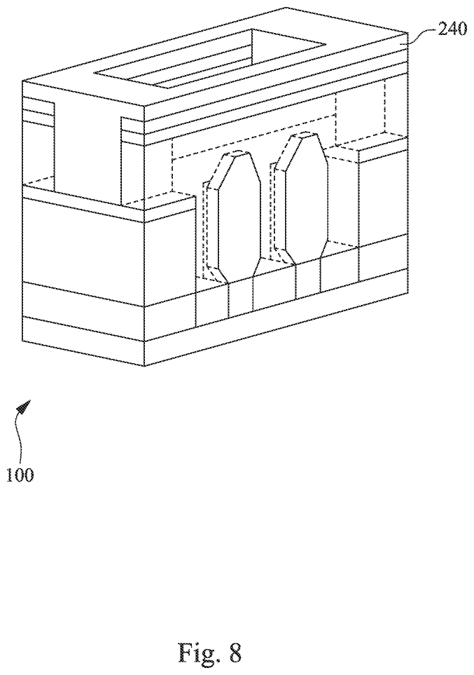

In FIGS. 19 and 8-10, method 1000 includes, at S13, etching through hard mask 240 and electrode layer 225 and landing on the metal gate electrode layer 223 of the metal gate 220.

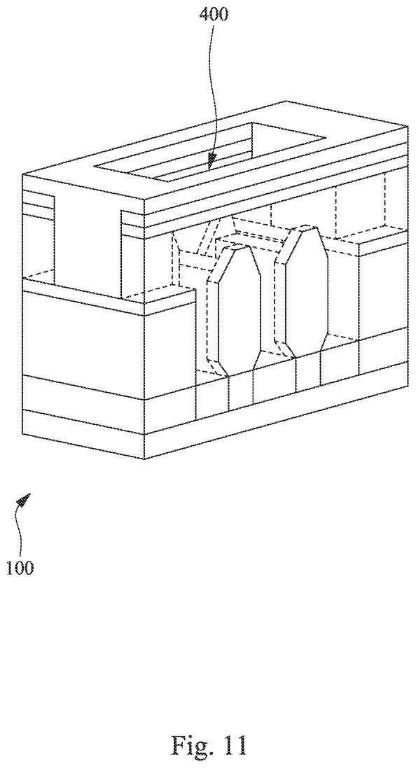

In FIGS. 19 and 11-13, method 1000 includes, at S14, etching through the metal gate electrode layer 223, WFM 222, and gate dielectric 221 of the metal gate 220. As a result, the fins 205 and STI 208 are uncovered and form a bottom trench surface 410 of a trench 400.

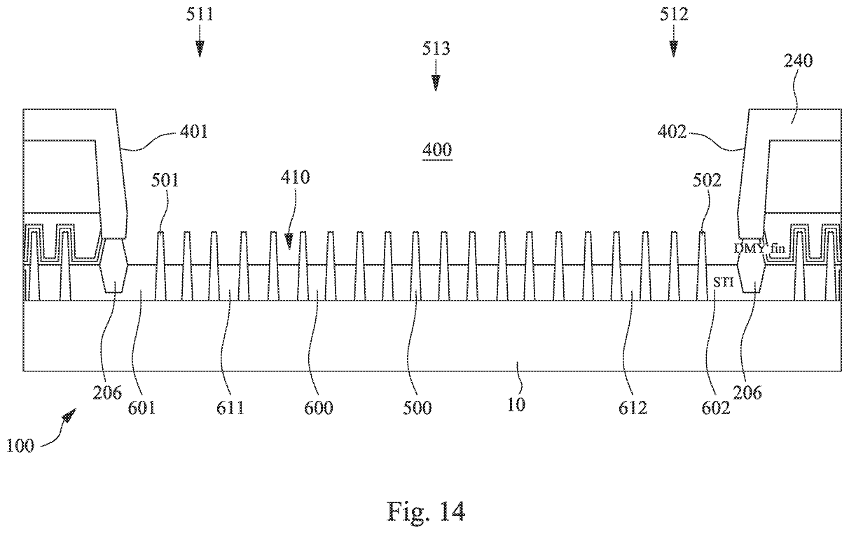

FIG. 14 is a Y-cut view, similar to FIG. 13, but illustrating a larger trench 400 with a greater number of fins, now numbered 500, and isolation regions, now numbered 600, and illustrating the underlying substrate 10 for descriptive purposes. In FIG. 14, the trench 400 is bounded by sidewalls 401 and 402. As shown, trench sidewalls 401 and 402 are formed by dummy fins 206 and hardmask 240.

In FIG. 14, a field of twenty fins 500 is illustrated in the trench 400; however, any suitable number of fins 500 may be provided in the trench 400. In some embodiments, at least three fins 500, or at least four fins 500, are located in the trench 400 between the sidewalls 401 and 402.

The isolation regions 600 may be considered to include terminal isolation regions 601 and 602 that are immediately adjacent to the trench sidewalls 401 and 402.

The fins 500 may be considered to include terminal fins 501 and 502 that are immediately adjacent to the trench sidewalls 401 and 402, i.e., are separated from the trench sidewalls 401 and 402 only by the terminal isolation regions 601 and 602.

Further, the fins 500 and isolation regions 600 may be categorized as being located in a first region 511 adjacent trench sidewall 401, a second region 512 adjacent trench sidewall 402, and a central region 513 located between the first region 501 and the second region 502.

As shown, the first region 511 includes the terminal isolation layer segment 601 and intermediate isolation layer segments 611 located between the terminal layer segment 601 and the central region 513; the second region 512 is formed with a terminal isolation layer segment 602 and with intermediate isolation layer segments 612 located between the terminal layer segment 611 and the central region 513.

Thus, method 1000 includes, at S11 through S14, providing a semiconductor structure with a first sidewall 401 distanced from a second sidewall 402, fins 500 located between the first sidewall 401 and the second sidewall 402, and isolation regions 600 located between the first sidewall 401 and the second sidewall 402, wherein adjacent fins 500 are separated by a respective isolation region 600.

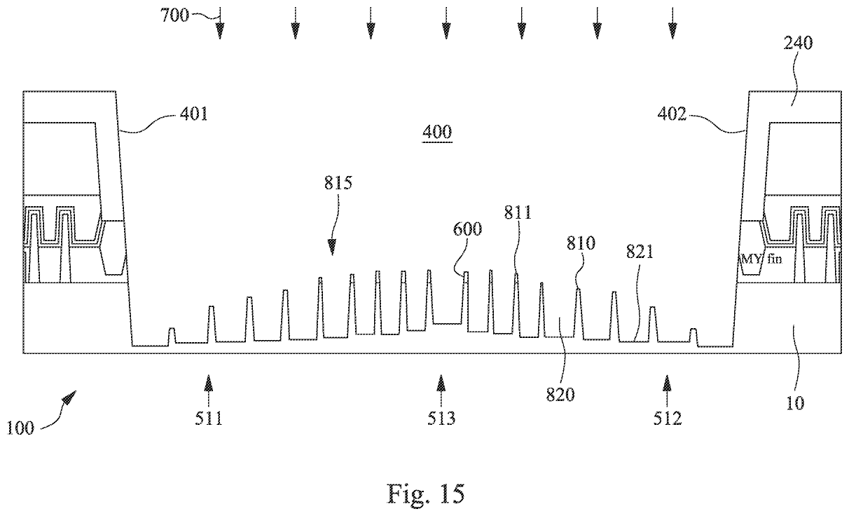

Cross-referencing FIGS. 19 and 15, method 1000 further includes, at S15, performing an etching process to etch the fins 500 and the isolation regions 600. In some embodiments, the etching process is a plasma etching process that chemically etches the fins 500 and physically etches the isolation regions 600. In some embodiments, the etching process etches the isolation regions 600, and the substrate 10 lying under the isolation regions 600 to surfaces 811 defining a crown-shaped depth profile. In some embodiments, the etching process etches the isolation layer 600 in first region 511 and second region 512 to a first depth and etches the isolation layer 600 in central region 513 to a second depth, wherein the first depth is deeper than the second depth.

As shown in FIG. 15, in a plasma etching process, plasma ions are directed toward the bottom trench surface 410 in the vertical direction of arrows 700. The plasma ions are positively charged. At the commencement of the etching process, negatives charges build-up on the trench sidewalls 401 and 402. As result, the plasma ions are attracted out of the vertical direction and toward the trench sidewalls 401 and 402. Plasma ions directed toward the central region 513 may be pulled toward regions 511 or 512. Plasma ions directed toward region 511 may be directed into sidewall 401. Plasma ions directed toward region 512 may be directed into sidewall 402. The plasma ions that strike trench sidewalls 401 and 402 may be reflected toward the bottom trench surface 410 while retaining a large fraction of their energy. As a result, the ion bombardment adjacent to the trench sidewalls 401 and 402 is greater than at locations more distant from the trench sidewalls 401 and 402. In other words, the ion bombardment in regions 511 and 512 is greater than in region 513.

The plasma bombardment is of particular relevance to the physical etching of material. In some embodiments, the etchant and conditions of the plasma etching process are selected so that the etching of the isolation regions 600 is dominated by physical etching while the etching of the fins 500 is dominated by chemical etching.

As a result, the fins 500 and the substrate 10 located under fins 500 are etched to a substantially same depth, i.e., the charged sidewalls 401 and 402 and non-vertical flow of positive ions does not greatly affect the chemical etching of the fins 500 in different regions 511, 512 and 513.

However, because physical etching dominates the etching of the isolation regions 600, the isolation regions 600 and the substrate 10 located under the isolation regions 600 are etched more, i.e., to greater depths, near the trench sidewalls 401 and 402, and are etched less, i.e., to shallower depths, farther from the trench sidewalls 401 and 402 due to the attraction of ions toward the sidewalls 401 and 402. In other words, the isolation regions 600 and the substrate 10 located under the isolation regions 600 are etched more deeply in regions 511 and 512 and less deeply, i.e., to shallower depths, in region 513. Moreover, the change in etched depths may form a smooth gradient and define a crown-shaped profile 815.

In some embodiments, the chemical etching of the fins 500 achieves a greater depth than the physical etching of the isolation regions 600, i.e., a minimum depth etched under the fins 500 is greater than a maximum depth etched under the isolation regions 600. Thus, the etched surface 800 is formed with projections 810, formed under or including isolation regions 600, that are separated by recesses 820, formed under fins 500. Further, due to the differential physical etching, the projections 810 are formed with uppermost surfaces 811 that define the crown-shaped depth profile 815. The recesses 820 are formed with lowest surfaces 821.

In some embodiments, performing the plasma etching process to etch the fins 500 and the isolation regions 600 may include completely removing the fins 500 and isolation regions 600 and etching into the semiconductor substrate 10 under each fin 500 and under each isolation region 600. In other embodiments, portions of isolation regions 600 or of some isolation regions 600 may remain after the etching process is completed, as shown in FIG. 15.

In some embodiments, the fins 500 are silicon, the isolation regions are silicon oxide, and the plasma etching process is performed with hydrogen bromide (HBr) as the etchant, such as in an HBrO2 etching process.

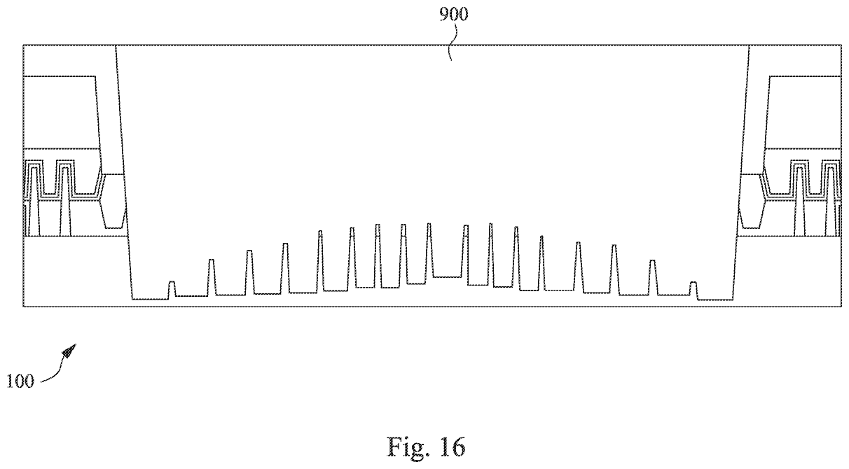

Cross-referencing FIGS. 19 and 16, method 1000 may continue at S16 with filling the trench 400 with dielectric to form an isolation structure 850. Method 1000 may continue at S17 with further processing to complete fabrication.

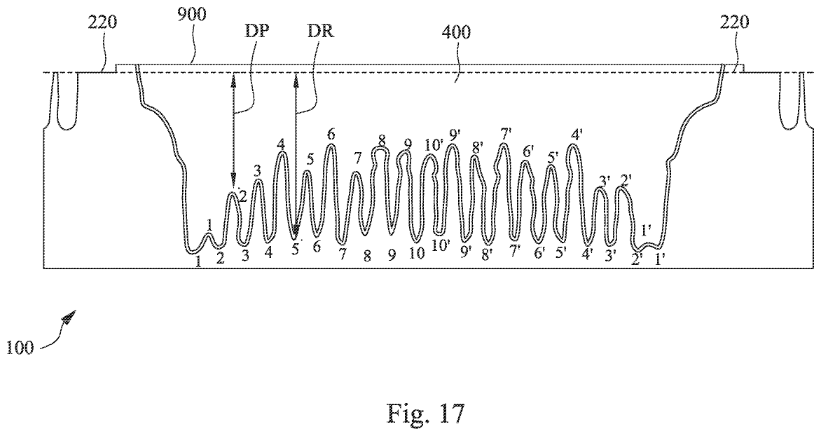

Referring now to FIG. 17, a transmission electron microscope (TEM) image of a portion of a semiconductor device 100 is provided. In the embodiment of FIG. 16, the etching process forms nineteen projections 810, labeled 1, 2, 3, 4, 5, 6, 7, 8, 9, 10′, 9′, 8′, 7′, 6′, 5′, 4′, 3′, 2′, and 1′, and twenty recesses 820, labeled 1, 2, 3, 4, 5, 6, 7, 8, 9, 10, 10′, 9′, 8′, 7′, 6′, 5′, 4′, 3′, 2′, and 1′ in trench 400.

As shown, the trench 400 is located between two metal gates 220. A plane 900 is defined by the top surface of the metal gates 220.

The uppermost surface 811 of each projection 810 is located at a vertical depth or distance DP below the plane 900. The lowest surface 821 of each recess is located at a vertical depth or distance DR below the plane 900.

Table 1 provides average, maximum, and minimum values for depth DP for each projection.

TABLE 1

| Projection | Average (nm) | Max (nm) | Min(nm) |
|---|---|---|---|
| 1 | 157 | 174 | 140 |
| 2 | 139 | 146 | 133 |
| 3 | 111 | 119 | 103 |
| 4 | 91 | 93 | 90 |
| 5 | 132 | 142 | 122 |
| 6 | 90 | 91 | 89 |
| 7 | 104 | 111 | 97 |
| 8 | 88 | 90 | 86 |
| 9 | 93 | 93 | 92 |
| 10 | 102 | 109 | 95 |
| 9′ | 92 | 95 | 90 |
| 8′ | 107 | 117 | 97 |
| 7′ | 95 | 98 | 92 |
| 6′ | 103 | 111 | 95 |
| 5′ | 111 | 129 | 93 |
| 4′ | 108 | 124 | 93 |
| 3′ | 130 | 131 | 129 |
| 2′ | 130 | 131 | 129 |
| 1′ | 160 | 185 | 136 |

As shown, the variance in depths DP for projections 810 is great. For example, the overall maximum depth DP (185 nm) is over twice as large as the overall minimum DP (86 nm). Further, the terminal projections, 1 and 1′, are etched significantly more than even the immediately adjacent projections, 2 and 2′. Also, the depths DP are much smaller in region 513 as compared to regions 511 and 512.

Table 2 provides average, maximum, and minimum values for depth DR for each recess.

TABLE 2

| Recess | Average (nm) | Max (nm) | Min(nm) |
|---|---|---|---|
| 1 | 187 | 191 | 183 |
| 2 | 185 | 187 | 183 |
| 3 | 184 | 184 | 183 |
| 4 | 176 | 181 | 172 |
| 5 | 177 | 178 | 175 |
| 6 | 182 | 187 | 177 |
| 7 | 179 | 184 | 174 |
| 8 | 175 | 176 | 173 |
| 9 | 172 | 172 | 172 |
| 10 | 181 | 183 | 180 |
| 10′ | 176 | 178 | 174 |
| 9′ | 179 | 179 | 178 |
| 8′ | 181 | 184 | 178 |
| 7′ | 180 | 181 | 179 |
| 6′ | 178 | 179 | 178 |
| 5′ | 182 | 182 | 182 |
| 4′ | 186 | 188 | 184 |
| 3′ | 186 | 187 | 185 |
| 2′ | 188 | 191 | 185 |
| 1′ | 186 | 190 | 183 |

As shown in Table 2, the depths DR of the recesses are substantially the same. For example, the overall minimum depth DR (172 nm) is within 10% of the overall maximum depth (191 nm). Further, there is no systemic difference in depths DR between regions 511, 512, and 513.

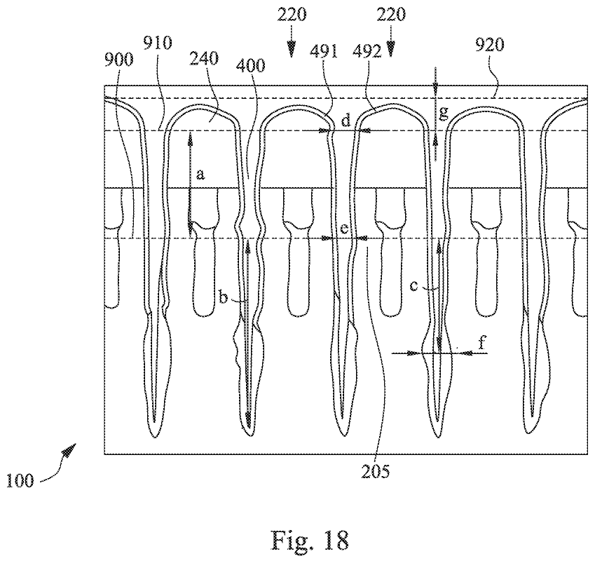

FIG. 18 is a transmission electron microscope (TEM) image of a portion of a semiconductor device 100 along an X-cut. As shown, in the X-direction, trenches 400 are formed between adjacent metal gates 220.

In FIG. 18, a plane 900 is defined at the top of the metal gates 220. Further, a gate height a is defined from the plane 900 to a plane 910 defined by the uppermost surface of the gates. Also, a depth b is defined from the plane 900 to the bottom of the trench 400. Each trench 400 is formed with a bowed shape having a maximum width f at a depth c from the plane 900.

Further, a horizontal width or critical dimension (CD) d between adjacent surfaces of hardmask 240 is defined at plane 910. Also, a horizontal width or critical dimension (CD) e between adjacent fins 205 is defined at plane 900.

In FIG. 18, a plane 920 is defined by the uppermost surface of the hardmask 240. Further, a vertical distance or height g of the hardmask 240 from plane 910 to plane 920 is defined.

Table 3 presents average, maximum, and minimum dimensions for measurements a through g, in accordance with some embodiments.

TABLE 3

| | | Average (nm) | Max (nm) | Min(nm) |
|---|---|---|---|---|
| a | Gate Height | 96.3 | 97.4 | 95.3 |
| b | Depth | 185.9 | 199.3 | 175.3 |
| c | Bowing Depth | 104.1 | 114.0 | 93.6 |
| d | Hard Mask CD | 26.8 | 28.1 | 25.5 |
| e | Fin CD | 20.7 | 23.7 | 18.9 |
| f | Bowing CD | 25.7 | 28.3 | 23.3 |
| g | Hard Mask Remain | 33.7 | 35.4 | 31.2 |

Cross-referencing FIGS. 11-13 and 18, the trench 400 is formed with a first end wall 491 distanced from a second end wall 492 in the X-direction. As shown, the first end wall 491 is located between a gate structure and the second end wall 492, and the second end wall 492 is located between a second gate structure and the first end wall 491. After performing the plasma etching process, a maximum critical dimension in the X-direction from the first end wall to the second end wall at a height of the first gate structure and the second gate structure, i.e., fin critical dimension e is 25 nanometers (nm), such as 24.5 nm, 24 nm, or 23.7 nm. After performing the plasma etching process, a maximum critical dimension, i.e., bowing CD f, in the X-direction from the first end wall 491 to the second end wall 492 at a bowing depth c is 30 nanometers (nm), such as 29.5 nm, 29 nm, 28.5 nm, or 28.3 nm.

As described above, methods herein provide for forming trenches, such as during a CPODE process, which have greater depths nearest the trench sidewalls. As a result, isolation structures formed within the trenches provide for improved protection against current leakage at the line edge. Further, the methods described herein may be used in high aspect ratio etching and provide a unique depth distribution. The methods provide a selective etch to remove a small etch amount, providing for a low risk of damage to epitaxial source/drain regions.

A method is provided and includes providing a semiconductor structure with a first sidewall distanced from a second sidewall, fins located between the first sidewall and the second sidewall, and isolation regions located between the first sidewall and the second sidewall, wherein adjacent fins are separated by a respective isolation region; and performing a plasma etching process to etch the fins and the isolation regions, wherein the plasma etching process chemically etches the fins, wherein the plasma etching process physically etches the isolation regions to surfaces defining a crown-shaped depth profile.

In some embodiments of the method, performing the plasma etching process includes chemically etching the fins to a substantially same depth.

In some embodiments of the method, the fins and the isolation regions are located over a semiconductor material, and wherein performing the plasma etching process to etch the fins and the isolation regions includes etching into the semiconductor material under each fin and under each isolation region.

In some embodiments of the method, the fins and the isolation regions are located over a semiconductor material, wherein performing the plasma etching process to etch the fins and the isolation regions includes etching into the semiconductor material under each fin and under each isolation region, and wherein a minimum depth etched under the fins is greater than a maximum depth etched under the isolation regions.

In some embodiments of the method, the fins are silicon, wherein the isolation regions are silicon oxide, and wherein the plasma etching process is performed with hydrogen bromide (HBr) as the etchant.

In some embodiments of the method, at least three fins are located between the first sidewall and the second sidewall.

In some embodiments of the method, the first sidewall is distanced from the second sidewall in a Y-direction; providing the semiconductor structure includes providing the semiconductor structure with a first end wall distanced from a second end wall in an X-direction perpendicular to the Y-direction, with the first end wall located between a first gate structure and the second end wall, and with the second end wall located between a second gate structure and the first end wall; after performing the plasma etching process, a maximum critical dimension in the X-direction from the first end wall to the second end wall at a height of the first gate structure and the second gate structure is 25 nanometers (nm).

In some embodiments of the method, the first sidewall is distanced from the second sidewall in a Y-direction; providing the semiconductor structure includes providing the semiconductor structure with a first end wall distanced from a second end wall in an X-direction perpendicular to the Y-direction, with the first end wall located between a first gate structure and the second end wall, and with the second end wall located between a second gate structure and the first end wall; after performing the plasma etching process, a maximum critical dimension in the X-direction from the first end wall to the second end wall at a height below the first gate structure and the second gate structure is 30 nanometers (nm).

In another embodiment, a method is provided and includes forming a field of fins extending up from an isolation layer in a first region, a second region, and a central region located between the first region and the second region; and performing an etching process to etch the isolation layer, wherein the etching process etches the isolation layer in the first region and second region to a first depth and etches the isolation layer in the central region to a second depth, wherein the first depth is deeper than the second depth.

In some embodiments of the method, performing the etching process includes etching the fins to a third depth, wherein the third depth is deeper than the first depth.

In some embodiments of the method, performing the etching process includes chemically etching the fins and physically etching the isolation layer.

In some embodiments of the method, the first region is formed with a terminal isolation layer segment and with intermediate isolation layer segments located between the terminal layer segment and the central region; the second region is formed with a terminal isolation layer segment and with intermediate isolation layer segments located between the terminal layer segment and the central region; and performing the etching process includes etching the terminal layer segment to a maximum first depth and etching the intermediate isolation layer segments to shallower first depths.

In some embodiments of the method, the fins and isolation layer are formed overlying a semiconductor substrate; and wherein performing the etching process includes removing the isolation layer, removing the fins, and recessing the semiconductor substrate to form a trench.

In some embodiments, the method further includes depositing dielectric material in the trench to define an edge of a semiconductor device.

In some embodiments of the method, the field of fins extending up from the isolation layer is formed adjacent to a metal gate structure having an uppermost surface; the first depth is greater than 130 nanometers (nm); and the second depth is less than 130 nanometers (nm).

In some embodiments of the method, performing the etching process includes etching the fins to a third depth; and the third depth is greater than 160 nanometers (nm).

In another embodiment, a semiconductor device is provided and includes a gate structure formed over a semiconductor substrate; a trench formed in the semiconductor substrate adjacent to the gate structure, wherein: the semiconductor substrate is formed with a trench bottom surface under the trench; the trench bottom surface includes spaced apart projections separated by recesses; each projection has an uppermost surface; and the uppermost surfaces of the projections located nearer to the gate structure are located at a greater depth than the uppermost surfaces of the projections located at a center of the trench; and a dielectric material located in the trench.

In some embodiments of the device, the vertical depth of each recess, measured from a top surface of the gate structure, is greater than 170 nanometers (nm); and the vertical depth of each uppermost surface, measured from the top surface of the gate structure, is less than 170 nanometers (nm).

In some embodiments of the device, each recess has a lowest surface, and wherein the lowest surfaces are located at depths within ten percent of one another.

In some embodiments of the device, the uppermost surfaces of the projections define a crown-shape profile.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A method comprising:
providing a semiconductor structure with a first sidewall distanced from a second sidewall, fins located between the first sidewall and the second sidewall, and isolation regions located between the first sidewall and the second sidewall, wherein adjacent fins are separated by a respective isolation region; and
performing a plasma etching process to etch the fins and the isolation regions, wherein the plasma etching process chemically etches the fins, wherein the plasma etching process physically etches the isolation regions to surfaces defining a crown-shaped depth profile.

2. The method of claim 1, wherein performing the plasma etching process comprises chemically etching the fins to a substantially same depth.

3. The method of claim 1, wherein the fins and the isolation regions are located over a semiconductor material, and wherein performing the plasma etching process to etch the fins and the isolation regions comprises etching into the semiconductor material under each fin and under each isolation region.

4. The method of claim 1, wherein the fins and the isolation regions are located over a semiconductor material, wherein performing the plasma etching process to etch the fins and the isolation regions comprises etching into the semiconductor material under each fin and under each isolation region, and wherein a minimum depth etched under the fins is greater than a maximum depth etched under the isolation regions.

5. The method of claim 1, wherein the fins are silicon, wherein the isolation regions are silicon oxide, and wherein the plasma etching process is performed with hydrogen bromide (HBr) as an etchant.

6. The method of claim 1, wherein at least three fins are located between the first sidewall and the second sidewall.

7. The method of claim 1, wherein:
the first sidewall is distanced from the second sidewall in a Y-direction;
providing the semiconductor structure comprises providing the semiconductor structure with a first end wall distanced from a second end wall in an X-direction perpendicular to the Y-direction, with the first end wall located between a first gate structure and the second end wall, and with the second end wall located between a second gate structure and the first end wall;
after performing the plasma etching process, a maximum critical dimension in the X-direction from the first end wall to the second end wall at a height of the first gate structure and the second gate structure is 25 nanometers (nm).

8. The method of claim 1, wherein:
the first sidewall is distanced from the second sidewall in a Y-direction;
providing the semiconductor structure comprises providing the semiconductor structure with a first end wall distanced from a second end wall in an X-direction perpendicular to the Y-direction, with the first end wall located between a first gate structure and the second end wall, and with the second end wall located between a second gate structure and the first end wall;
after performing the plasma etching process, a maximum critical dimension in the X-direction from the first end wall to the second end wall at a height below the first gate structure and the second gate structure is 30 nanometers (nm).

9. A method comprising:
forming a field of fins extending up from an isolation layer in a first region, a second region, and a central region located between the first region and the second region; and
performing an etching process to etch the isolation layer, wherein the etching process etches the isolation layer in the first region and second region to a first depth and etches the isolation layer in the central region to a second depth, wherein the first depth is deeper than the second depth.

10. The method of claim 9, wherein performing the etching process comprises etching the fins to a third depth, wherein the third depth is deeper than the first depth.

11. The method of claim 10, wherein performing the etching process comprises chemically etching the fins and physically etching the isolation layer.

12. The method of claim 9, wherein
the first region is formed with a terminal isolation layer segment and with intermediate isolation layer segments located between the terminal isolation layer segment and the central region;
the second region is formed with a terminal isolation layer segment and with intermediate isolation layer segments located between the terminal isolation layer segment and the central region; and
performing the etching process comprises etching the terminal isolation layer segment to a maximum first depth and etching the intermediate isolation layer segments to shallower first depths.

13. The method of claim 9, wherein the fins and isolation layer are formed overlying a semiconductor substrate; and wherein performing the etching process comprises removing the isolation layer, removing the fins, and recessing the semiconductor substrate to form a trench.

14. The method of claim 13, further comprising depositing dielectric material in the trench to define an edge of a semiconductor device.

15. The method of claim 9, wherein:
the field of fins extending up from the isolation layer is formed adjacent to a metal gate structure having an uppermost surface;
the first depth is greater than 130 nanometers (nm); and
the second depth is less than 130 nanometers (nm).

16. The method of claim 15, wherein:
performing the etching process comprises etching the fins to a third depth; and
the third depth is greater than 160 nanometers (nm).

17. A semiconductor device comprising:
a gate structure formed over a semiconductor substrate;
a trench formed in the semiconductor substrate adjacent to the gate structure, wherein:
the semiconductor substrate is formed with a trench bottom surface under the trench;
the trench bottom surface includes spaced apart projections separated by recesses;
each projection has an uppermost surface; and
the uppermost surfaces of the projections located nearer to the gate structure are located at a greater depth than the uppermost surfaces of the projections located at a center of the trench; and
a dielectric material located in the trench.

18. The semiconductor device of claim 17, wherein:
a vertical depth of each recess, measured from a top surface of the gate structure, is greater than 170 nanometers (nm); and
a vertical depth of each uppermost surface, measured from the top surface of the gate structure, is less than 170 nanometers (nm).

19. The semiconductor device of claim 17, wherein each recess has a lowest surface, and wherein the lowest surfaces are located at depths within ten percent of one another.

20. The semiconductor device of claim 17, wherein the uppermost surfaces of the projections define a crown-shape profile.
